(19) United States
(12) Patent Application Publication
(10) Pub. No.: US 2014/0283901 A1
(43) Pub. Date: Sep. 25, 2014

(54) NANOSTRUCTURE, NANOSTRUCTURE FABRICATION METHOD, AND PHOTOVOLTAIC CELL INCORPORATING A NANOSTRUCTURE

(71) Applicants: Martin Aagesen, Hedehusene (DK); Henrik Ingerslev Jorgensen, Kobenhavn S (DK); Jeppe Vilstrup Holm, Kobenhavn N (DK); Morten Schaldemose, Kobenhavn O (DK)

(72) Inventors: Martin Aagesen, Hedehusene (DK); Henrik Ingerslev Jorgensen, Kobenhavn S (DK); Jeppe Vilstrup Holm, Kobenhavn N (DK); Morten Schaldemose, Kobenhavn O (DK)

(73) Assignee: GASP Solar APS, Hedehusene (DK)

(21) Appl. No.: 14/235,740

(22) PCT Filed: Jul. 17, 2012
(86) PCT No.: PCT/EP12/64035

§ 371 Date: May 8, 2014

Related U.S. Application Data
(60) Provisional application No. 61/513,018, filed on Jul. 29, 2011.

(30) Foreign Application Priority Data
Aug. 3, 2011 (GB) 1113464.0

(51) Int. Cl. H01L 31/0352; H01L 21/02; H01L 31/0304; H01L 29/20; H01L 29/06

(52) U.S. Cl. CPC H01L 31/035227; H01L 29/20; H01L 29/0669; H01L 31/03046; H01L 21/02543; H01L 21/02546; H01L 21/02653; H01L 21/02381; H01L 21/02488
USPC 136/255; 257/9; 257/28; 438/479

(57) ABSTRACT

The application discloses a technique for fabricating gallium-arsenide-phosphorous (GaAsP) nanostructures using gallium-assisted (Ga-assisted) Vapour-Liquid-Solid (VLS) growth, i.e. without requiring gold catalyst particles. The resulting Ga-assisted GaAsP nanostructures are free of gold particles, which renders them useful for optoelectronic applications, e.g. as a junction in a solar cell. The Ga-assisted GaAsP nanostructures can be fabricated with a band gap in the range 1.6 to 1.8 eV (e.g. at and around 1.7 eV).

### FIELD OF THE INVENTION

The invention relates to semiconductor nanostructures, such as nanowires or nano “flakes”, and is applicable, for example, in photovoltaic devices or the like.

### BACKGROUND TO THE INVENTION

Conventionally, a nanostructure is a material structure having at least one region or characteristic dimension whose size is in the nanometre range (i.e. ˜10⁻⁹ m). For example, the structure may be in the form of a plate whose thickness is in the nanometre range. Alternatively, the structure may be substantially one dimensional, wherein its transverse dimension is in the nanometre range. Quasi-one-dimensional nanostructure may be referred to as nanowires.

Growth of semiconductor nanowires was first discussed in 1964 by Wagner and Ellis. The nanowires they grew were catalyzed by means of a liquid gold catalyst particle and a nanowire growth mechanism named Vapour-Liquid-Solid (VLS) growth mechanism. This name derives from the fact that material(s) used for growing the wires are initially in a vapour or gas phase, then become incorporated into the liquid phase of the gold catalyst particle, and finally enter the solid phase in the nanowire itself. Generally, such nanowire growth was characterised by placing one or more gold catalyst particles on a growth substrate and subsequently introducing growth materials into the system, where they would be collected by the gold catalyst particle. At some point the gold particle would become supersaturated with the growth materials and start to nucleate the material underneath itself and in that way “grow” the nanowire. The diameter of the catalyst particle determined the diameter of the nanowire.

For some years, the preferred material for the catalyst has been gold. The growth of both silicon and group III-V semiconductor nanowires by means of gold catalyst particles has been investigated thoroughly and there is a large body of published literature on this topic.

An advantage of the small diameter of nanowires is that it is possible to grow them on non-lattice matched substrates, i.e. on substrates where the distance between the individual atoms in the crystal lattice is different from that in the nanowire. This advantage arises because the small diameter of the nanowire reduces or minimises the strain that it experiences. In an early article [1] describing gold-catalyzed growth of non-lattice matched gallium arsenide phosphide (GaAsP) III-V nanowires on silicon, the growth system used was a metal organic vapour phase epitaxy (MOVPE). Beside MOVPE, it is known how to fabricate group III-V semiconductor nanowires using molecular beam epitaxy (MBE).

Despite the interest in this area, a theoretical understanding of the nanowire growth has not developed to support the experimental data. In 2010, Frank Glas published an article [2] in which he calculated the chemical potential of the gold catalyst droplet as a function of its content of group III and group V atoms. In this article it was shown that the chemical potential of the gold droplet depended significantly on the amount of group V material inside the droplet. The difference in chemical potential of the catalyst droplet and the semiconductor surface it is lying on is a measure of the supersaturation of the droplet and hence the driving force for the nucleation of the nanowire below the droplet. The article included a theoretical calculation to show that, assuming a small amount of group V material was incorporated into the catalyst particle during nanowire growth, the chemical potential of the gold droplet would, for the same amount of group V material, be larger when growing gallium-phosphide (GaP) nanowires than when growing gallium-arsenide (GaAs) nanowires.

Recently a nanowire growth method has been developed which utilizes gallium as the particle for growing gallium-arsenide (GaAs) nanowires. This type of Ga-assisted growth is also know as self-assisted growth. The GaAs nanowires are grown either directly on a silicon substrate or on a substrate having a silicon oxide (SiOx) layer deposited on top prior to the nanowire growth [3, 4, 5]. The typical used crystal orientation of the substrate is (111). The use of gallium droplets to assist growth in this way means that the nanowires can be incorporated more readily onto silicon-based technology because gallium does not affect the electronic and semiconducting properties of silicon in the same way as gold, which can have detrimental effects on the properties of silicon [11].

The gallium-assisted GaAs nanowire growth mechanism is believed to be roughly identical to that of gold-catalyzed growth. It is thought that GaAs nanowire growth is initiated after the free gallium atoms, which move around on the silicon substrate, form gallium droplets, which then are supersaturated by the As material. When the droplets reach a certain critical amount of supersaturation they start to nucleate GaAs underneath. Since new gallium atoms are constantly being incorporated into the droplet during growth, the droplet remains throughout the growth unless the number of new gallium atoms incorporated in the droplet is smaller than the number of As atoms incorporated. It is known that self-assisted GaAs nanowires are preferred for optoelectronic applications [9].

Growth of indium-phosphide InP and InAsP without the use of gold have also been realised [6, 7]. However, at least for the case of InAs it is still debated whether or not a liquid particle is present during growth of the nanowires.

The use of group III-V semiconductor nanostructures in an active layer of a photovoltaic cell is known.

For example, U.S. Pat. No. 7,087,833 discloses a photovoltaic device that includes semiconductor nanostructures as at least a portion of a photoactive layer. Each nanostructure has a core made of a first material (e.g. GaAs) surrounded by a shell made of a second material (e.g. InP) that is different from the first material. The materials are selected to exhibit a type-II band offset profile, whereby one type of charge carrier created by incident light on the nanostructure is conducted through the core and the other type of charge carrier is conducted through the shell.

WO 2008/067824 discloses a photovoltaic device having an active layer in which core-shell type nanostructures having a flake-like (e.g. tapering planar) shape are grown on a substrate. In one example, InAs nanoflakes are grown on an GaAs substrate using a gold-catalysed VLS fabrication method.

### SUMMARY OF THE INVENTION

At its most general, the present invention provides a technique for fabricating gallium-arsenide-phosphorous (GaAsP) nanostructures using gallium-assisted (Ga-assisted) growth, i.e. without requiring gold catalyst particles. Whereas GaAsP nanostructures (e.g. thin films, nanowires, etc.) are known per se, the present invention teaches the ability to form such GaAsP nanostructures using Ga-assisted growth. As discussed below, the Ga-assisted GaAsP nanostructures of the invention may exhibit properties, e.g. band gap, that make them suitable for use as a junction in a solar cell. In particular, the present invention may provide GaAsP nanostructures to be fabricated with a band gap in the range 1.6 to 1.8 eV (e.g. at and around 1.7 eV).

Relative to conventional gold-assisted growth, Ga-assisted growth may result in fewer impurity atoms in the crystal that forms the nanostructure. In particular, it is known that gold-assisted VLS growth causes Au atoms to be incorporated into the nanostructure [10], which degrades their optoelectronic properties. The present invention enables the growth of GaAsP nanostructures which are completely free from Au impurities. Growth of such nanostructures have not been possible heretofore. The increased purity of the nanostructures of the invention may enable them to behave more efficiently in a solar cell. It is also possible that Ga-assisted growth may result in a more uniform distribution of As and P atoms in the nanostructure than can be produced using the conventional gold-assisted technique.

The direct growth of nanostructures having band gaps around 1.7 eV may be preferred to conventional AlGaAs or GaAsP fabrication techniques for two reasons. Firstly, direct growth may permit doping to be performed as part of the same process. One type of conventional GaAsP growth comprises selectively etching a bulk layer of material to form nanostructures followed by a separate subsequent doping step in order to create a core-shell p-i-n junction. Secondly, direct growth may be more robust with respect to crystal defects than e.g. a known technique of performed selective area GaAsP growth on patterned silicon substrates.

The formation of Ga-assisted GaAsP nanostructures is a non-trivial development from the known techniques of fabricating Ga-assisted GaAs nanostructures due to the unknown effect of phosphorous (P) in the fabrication environment. The present application is based on the discovery that the growth process needs to be controlled in a manner that goes against conventional knowledge in this field in order to generate GaAsP nanostructure growth from gallium droplets. In particular, the theory in existence before the invention was conceived tended to suggest that a much higher chemical potential would be needed in the Ga particle to be supersaturated with P in contrast with As. Accordingly, it was believed that either P would not readily be incorporated with As to supersaturate a Ga particle, or that the chemical potential of the Ga particle would rise so much that it would be completely crystallised and hence terminate growth. As explained below, the present invention has found a balance which unexpectedly enables Ga-assisted GaAsP nanostructure growth.

According to one aspect of the invention, there is provided a GaAsP nanostructure resulting from Ga-assisted growth. The GaAsP nanostructure may be free from gold impurities, i.e. the invention may provide an Au-free GaAsP nanostructure. The nanostructure may be a quasi-one-dimensional nanostructure such as a nanowire, nanoflake, nanorod, nanopillar, nanocone or the like. In one embodiment, the GaAsP nanostructure may be a GaAsP nanowire having a length ranging from a few hundred nanometres to a few micrometres, e.g. from 50 nm to 100 μm, such as 1 to 25 μm, and a maximum traverse dimension in the order of nanometres, e.g. 200 nm or less, preferably less than 150 nm, such as less than 120 nm, e.g. between 20 and 120 nm. The GaAsP nanostructure may be plate-like, e.g. resembling a flake, having a length ranging from a few hundred nanometres to a few micrometres, e.g. between 1 to 25 μm, a width in the range 100 nm to 2 μm, and a thickness in the order of nanometres, e.g. less than 120 nm. For example, the nanostructure may comprise a nanowire extending in a longitudinal direction, wherein the nanowire has a maximum transverse dimension less than 100 nm.

The nanostructure grown from a Ga particle may comprise Ga and group V material comprising As and P, wherein the proportion of As in the group V material is 65% to 90% and the proportion of P in the group V material is 10% to 35%. Preferably the proportion of P in the group V material is 15% to 30%. The nanostructure may also include dopant atoms, e.g. Be or Si or the like.

As mentioned above, the GaAsP in nanostructure may exhibit a band gap in the range 1.6 to 1.8 eV.

In another aspect, the invention may provide a semiconductor device comprising a silicon substrate having a plurality of the GaAsP nanostructures discussed above grown thereon by Ga-assisted growth. For example, the plurality of GaAsP nanostructures may comprise a plurality of nanowires, each nanowire extending in a longitudinal direction from a growth surface of the substrate, the longitudinal direction being offset from, e.g. substantially normal to the surface of the substrate. The surface of the substrate may have a <111> crystal orientation

The semiconductor device of this aspect may find particular use as the active element in a photovoltaic cell, and especially a multi-junction photovoltaic cell. The advantages of using nanostructures over conventional thin film arrangements in photovoltaic cells are well documented, see e.g. WO 2010/120233. An advantage of the present invention is that the silicon substrate on which the GaAsP nanostructures are grown can be used actively in a final device without any detrimental effects caused by diffusion of gold into the silicon that can occur with known Au-assisted GaAsP growth techniques.

In one embodiment of a multi-junction photovoltaic cell, according to the invention, the silicon in the substrate may form a first p-n junction and the GaAsP in the nanostructures forms a second p-n junction. The band gap of the first p-n junction may be different from (e.g. lower than) that of the second p-n junction to enable the cell to generate electricity from a broad range of wavelengths in the light spectrum.

Herein, a p-n junction may mean any arranged of a first region having a first conductivity type (e.g. p-conductivity) with respect to a second region having a second conductivity type different from (e.g. opposite to) the first conductivity type (e.g. n-conductivity) which promotes separation of charge carriers (i.e. electron-hole pairs) created by the absorption of photons in the first or second region to generate a voltage across the cell. For example, the first and second region may contact one another at an interface, thereby creating a p-n junction. Alternatively, in a preferred arrangement, a substantially intrinsic region may be located between the first and second regions to form a p-i-n junction.

In one embodiment, the silicon substrate may comprise a first silicon layer having a first conductivity type, and a second silicon layer having a second conductivity type, the first and second silicon layers being disposed to form the first p-n junction (or p-i-n junction), and each GaAsP nanostructure may have a core region surrounded by a shell region, the core region being formed from one of the first and second conductivity types (e.g. n⁺-doped GaAsP) and the shell region being formed from the other of the first and second conductivity types (e.g. p⁺-doped GaAsP) to form a second p-n junction (or p-i-n junction if a region (e.g. an inner shell region) of substantially intrinsic GaAsP is disposed between the core and shell regions).

A third p-n junction (e.g. a tunnel junction) may be provided between the first and second p-n junctions. The third p-n junction is formed in the silicon substrate or in each GaAsP nanostructure or at the interface between the Si substrate and the GaAsP nanostructures.

As is conventional, a first electrical contact may be formed on the back surface of the substrate (i.e. the surface opposite to the surface on which the GaAsP nanostructures are grown), and a second electrical contact may be formed on top and/or around the upper part of the GaAsP nanostructures or around the bottom lower part of the GaAsP nanostructures. The latter configuration may improve light absorption while preserving the carrier collecting properties of the electrode. The second electrical contact may also be formed by overgrowing the nanostructures and the surface between the structures with a conductive layer having suitable properties such that the nanowires are connected by the conductive layer. The conductive layer may then be contacted by a metal grid pattern or the like. The contacts are for connecting the photovoltaic cell to electrical devices to use or store the electricity generated therein. Any suitable conductors may be used. For example, the second electrical contact may comprise a transparent conductor, such as a conducting polymer or a layer of transparent conductive oxide (TCO), e.g. of indium tin oxide (ITO) or the like. The GaAsP nanostructure may be surrounded by (e.g. embedded in) an insulating filler material. Preferably the filler material is transparent to light having wavelengths corresponding to the band gap of the first p-n junction. The filler material may assist the nanostructures in supporting the second electrical contact. The filler may contain material, e.g. silver nanoparticles, which promote the reflection of light into the nanostructures. However, in other embodiments, the nanostructures may be surrounded by air.

The Ga-assisted growth of GaAsP nanostructures according to the invention may use molecular beam epitaxy (MBE) or any other epitaxial growth process capable of utilizing the Ga droplets for growth of nanostructures therefrom. For example, the invention may use metalorganic vapour-phase epitaxy (MOVPE), chemical beam epitaxy (CBE) or the like.

According to a third aspect of the invention, there may be provided a vapour-liquid-solid (VLS) method of growing a GaAsP nanostructure, the method comprising: subjecting a silicon oxide surface layer on a substrate (e.g. a silicon substrate) to a Ga flux to form Ga droplets on the surface layer; subjecting the Ga droplets to the Ga flux and a group V flux to supersaturate the Ga droplets with group V atoms from the group V flux, the group V flux comprising an As flux and, optionally, a P flux; setting a growth temperature, a non-zero proportion of P flux in the group V flux and the Ga flux and the group V flux in a V/III flux ratio to effect growth of a GaAsP nanostructure at each supersaturated Ga droplet. The Ga droplets may be formed when only a Ga flux is present, but this is not essential. If a group V flux is also present, the Ga flux may need to be increased to cause formation of the Ga droplets.

This disclosure is based on the discovery that the proportion of P in the group V flux has an effect on the formation on Ga droplets on the substrate and an unexpected relationship to the amount of P present in produced GaAsP nanostructure. The invention proposes a technique which takes these effects into account, together with growth temperature and V/III flux ratio, during fabrication in order to achieve Ga-assisted GaAsP nanostructure growth.

In one embodiment, the method may include setting the proportion of P flux in the group V flux as a predetermined multiple of the proportion of P relative to the total amount of group V atoms to be present in the grown GaAsP nanostructure. The proportion of P flux in the group V flux affects the proportion of P in the group V atoms of the GaAsP nanostructure in a repeatable manner for given growth conditions (e.g. molecular composition of beam flux, growth temperature, group V/III flux ratio, etc.). Surprisingly, the multiple itself is much lower than what would be expected for conventional GaAsP bulk (i.e. thin film) growth. If the MBE growth technique is used, the multiple may depend on the molecular composition of the P flux and As flux. For example, if the P flux delivers P₂ molecules and the As flux in the group V flux delivers As₄ molecules, the predetermined multiple may be in the range 0.1 to 2 (preferably 0.25 to 1.5), which may be five to twenty times lower than the equivalent multiple in GaAsP bulk growth. If As₂ molecules are used, the parameters may be adapted accordingly since As₂ is known to incorporate more effectively into the crystal during growth than As₄. For example, the predetermined multiple may be in the range 0.2 to 6 if As₂ is used. If the MOVPE growth system is used, there may be a larger amount of carrier gases which can be used to supply the As or P atoms to the growth site. The effectiveness of these carrier gases may vary and therefore the predetermined multiple may be determined from the known effectiveness of each of the carrier gases when used for bulk thin film growth.

The method may including selecting the predetermined multiple based on the growth temperature and the group V/III flux ratio, e.g. to create a GaAsP nanostructure having a desired proportion of P atoms in its group V atoms. For example, if it is desirable to obtain 22% P atoms in the group V atoms of the nanostructure, the method may include determining (e.g. calculating or looking up) the multiple needed to achieve that proportion for a given growth temperature and group V/III flux ratio. For example, if the growth temperature was 630° C. and the group V/III flux ratio 50, the multiple may be determined as 0.55, in which case the proportion of P flux in the group V flux would be set as 12%. Of course, a similar determination may be undertaken to determine the growth temperature and/or group V/III flux ratio to ensure that a given proportion of P flux in the group V flux yields a desired proportion of P atoms in the group V atoms of the grown GaAsP nanostructure.

This may be particularly important if it is desirable to overgrow the nanowire with bulk (thin film) layers of GaAsP, e.g. to form a p-n junction or the like. It may be desirable to match the proportion of P atoms in the group V atoms of the deposited bulk layer with the proportion of P atoms in the group V atoms of the nanowire. Accordingly, it may be necessary to increase or decrease the proportion of P flux in the group V flux for the bulk growth. If the same growth parameters are used, it is likely that the bulk layer will contain less than half (more likely less than a fifth) of the proportion of P atoms that has been obtained in the nanowires.

A non-zero group V flux may be present in addition to the Ga flux during formation of the Ga droplets on the substrate surface. The group V flux may comprise an As flux and/or a P flux. The present disclosure also teaches that the presence of P in the group V flux during Ga droplet formation and growth initiation affects the maximum V/III flux ratio that can be used for a given growth temperature to ensure formation of the Ga droplets. This is important, because it may be desirable to perform Ga-assisted GaAsP nanostructure growth close to the maximum available V/III flux ratio to form high quality nanostructures. The presence of a P flux in the group V flux during Ga droplet formation means that the maximum V/III flux ratio for a given temperature is lower than what can be used for the known Ga-assisted GaAs growth discussed above.

The method may therefore include changing (e.g. increasing) the proportion of P flux in the group V flux after forming the plurality of Ga droplets. That is, a different V/III flux ratio and proportion of P flux in the group V flux may be used when forming the Ga droplets compared with when supersaturating the droplets and initiating growth.

Thin film growth of GaAsP is typically performed at around 450-490° C. Moreover, whilst the amount of P in the thin film increases slightly compared to As with an increase in growth temperature, this effect saturates at substrate temperatures above 550° C. [8]. In contrast, the set growth temperature in the invention may be higher than 550° C., e.g. higher than 620° C. and/or up to 660° C. In one embodiment, the growth temperature may be in the range 620° C. to 660° C. and the V/III flux ratio may be less than 70.

The invention may include forming a passivation layer (e.g. of silicon monoxide or silicon dioxide), on the substrate before subjecting it to the Ga flux. The Ga atoms in the droplet locally dissolve the oxide layer to create contact between the supersaturated Ga droplet and the substrate body (e.g. silicon), whereby GaAsP growth begins. If the GaAsP nanostructure has a core region surrounded by a shell region, the passivation layer may also act to insulate the substrate body (e.g. n-type silicon) from the shell region (e.g. n-type GaAsP) shell, since otherwise it may short to the silicon substrate surface.

Alternatively, the method may include, before subjecting the silicon oxide surface to a Ga flux, etching a plurality of holes in the silicon oxide surface layer to create an array of oxide free holes for receiving the Ga droplets in direct contact with the silicon. Direct contact with the silicon is desirable because it can improve the conversion efficiency between the nanostructure and the silicon, e.g. when used in a solar cell. However, direct contact was undesirable with known Au-catalysed growth, because the Au particles could diffuse into the silicon and adversely affect its properties. The array of oxide free holes may be formed by nanoimprint lithography.

The method may also include doping the nanostructure, e.g. by introducing a dopant flux (e.g. generating a conductivity type other than the grown nanostructure) during growth, or by overgrowing each nanostructure with a doped GaAsP shell (e.g. a coating), and then causing diffusion of doping atoms from the overgrown doped shell into the nanowire.

It is desirable to obtain good crystal quality for the grown nanowires e.g. to facilitate use in solar cells. If the grown nanowires contain crystal defects or changes in the crystal orientation (like twinning defects) the optical-electrical properties of the nanowires themselves may be significantly degraded. During a subsequent shell growth around the nanowires (e.g. to form a p-n junction as discussed above) the crystal defects, or twinning defects, may become further pronounced such that the quality of the grown shell may become significantly worse than the crystal quality of the nanowires. It is therefore very desirable to obtain growth parameters which results in single crystal nanowires without defects. Conventional GaAs nanowires can be grown in a significantly larger parameter space than perfect single crystal GaAs nanowires, so it is a challenge to obtain good crystal quality even for GaAs. The present invention adds P into the nanowire growth, and hence the optimal parameter space becomes even smaller. It is desirable to determine the influence of the phosphorus on critical growth conditions for obtaining good crystal quality, such as supersaturation. Too high a supersaturation may cause twinning defects. High supersaturation can be caused by a high P flux.

### BRIEF DESCRIPTION OF THE DRAWINGS

Examples of the invention are discussed in detail below with reference to the accompanying drawings, in which:

FIGS. 1A, 1B and 1C shows the results of MBE-based nanostructure growth for differing proportions of P flux in the group V flux;

FIGS. 2A, 2B and 2C show the results of MBE-based GaAsP nanostructure growth according to embodiments of the invention;

FIGS. 3A and 3B show schematically the results of energy-dispersive X-ray (EDX) spectroscopy in Ga-assisted growth GaAsP nanowires that are embodiments of the invention;

FIGS. 4A and 4B show schematically the results of energy-dispersive X-ray (EDX) spectroscopy in Ga-assisted growth GaAsP nanowires that are further embodiments of the invention;

FIGS. 5A and 5B show schematically the results of energy-dispersive X-ray (EDX) spectroscopy in Ga-assisted growth GaAsP nanowires that are yet further embodiments of the invention;

FIGS. 6A and 6B show schematically the results of energy-dispersive X-ray (EDX) spectroscopy in Ga-assisted growth GaAsP nanowires that are yet further embodiments of the invention; and

FIG. 7 is a schematic representation of the active element in a photovoltaic cell that is an embodiment of the invention.

FIGS. 8A and 8B are SEM images of two MBE-based growths of GaAsP nanowires that are further embodiments of the invention.

### DETAILED DESCRIPTION; FURTHER OPTIONS AND PREFERENCES

In the examples of the invention discussed below, molecular beam epitaxy was used as the growth technique. However, the teaching herein may be equally applicable to other epitaxial growth techniques, e.g. MOVPE.

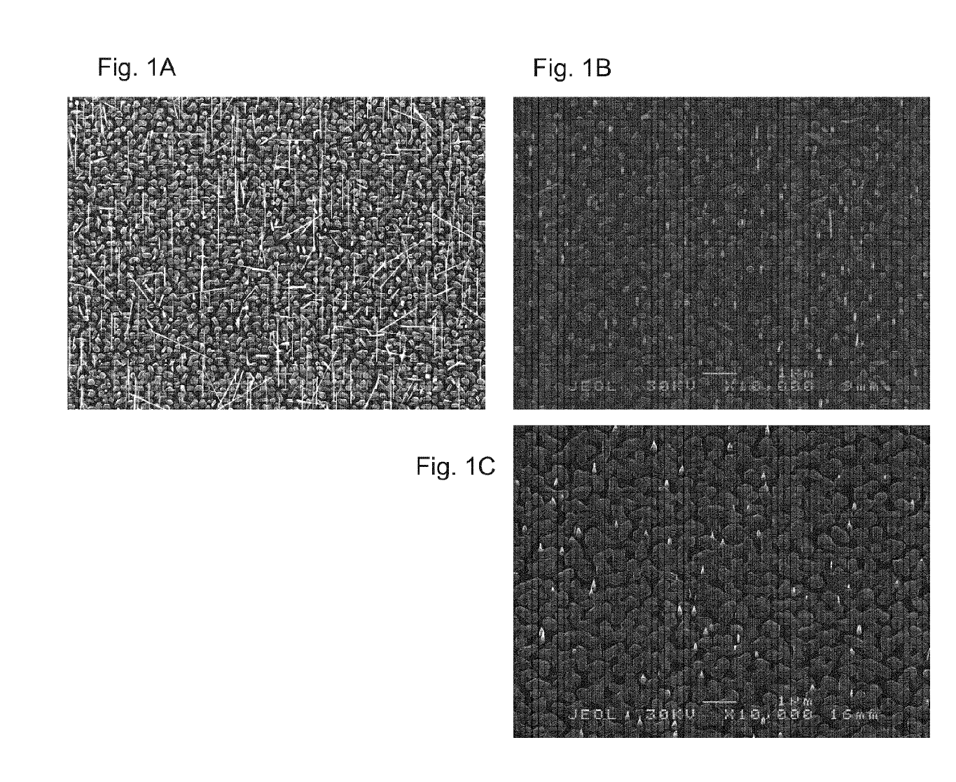

FIGS. 1A, 1B and 1C show three nanostructure growths which illustrate that the maximum group V/III ratio which can be used in the MBE configuration for these Ga-assisted GaAsP growth is lower than what can be used for the known Ga-assisted GaAs growth.

The experimental parameters used for the growths shown in FIGS. 1A, 1B and 1C are shown in the following tables. The flux parameters are expressed as beam equivalent pressures in Torr (1 Torr being approximately 133.3 Pa). The growth temperatures were measured with a pyrometer.

| | | | | Time | Temperature |
|---|---|---|---|---|---|
| FIG. 1A | Ga flux | As flux | P flux | (mins) | (° C.) |
| Growth | 8.72 × 10⁻⁸ | 1.06 × 10⁻⁵ | — | 20 | 630 |

| | | | | Time | Temperature |
|---|---|---|---|---|---|
| FIG. 1B | Ga flux | As flux | P flux | (mins) | (° C.) |
| Growth | 8.72 × 10⁻⁸ | 5.3 × 10⁻⁶ | 5.3 × 10⁻⁶ | 20 | 630 |

| | | | | | Tem- |
|---|---|---|---|---|---|
| | | | | | pera- |
| | | | | Time | ture |
| FIG. 1C | Ga flux | As flux | P flux | (mins) | (° C.) |
| Init | 8.72 × 10⁻⁸ | 8.72 × 10⁻⁶ | 0.20 × 10⁻⁶ | 4 | 629 |
| Growth 1 | 8.72 × 10⁻⁸ | 8.28 × 10⁻⁶ | 0.43 × 10⁻⁶ | 3 | 629 |
| Growth 2 | 8.72 × 10⁻⁸ | 8.72 × 10⁻⁶ | 0.20 × 10⁻⁶ | 1 | 629 |
| Growth 3 | 8.72 × 10⁻⁸ | 7.85 × 10⁻⁶ | 0.87 × 10⁻⁶ | 3 | 629 |
| Growth 4 | 8.72 × 10⁻⁸ | 8.72 × 10⁻⁶ | 0.20 × 10⁻⁶ | 1 | 629 |
| Growth 5 | 8.72 × 10⁻⁸ | 6.98 × 10⁻⁶ | 1.74 × 10⁻⁶ | 3 | 629 |
| Growth 6 | 8.72 × 10⁻⁸ | 8.72 × 10⁻⁶ | 0.20 × 10⁻⁶ | 1 | 629 |
| Growth 7 | 8.72 × 10⁻⁸ | 6.11 × 10⁻⁶ | 2.61 × 10⁻⁶ | 3 | 629 |

The two growths shown in FIG. 1A and FIG. 1B thus used identical growth parameters (i.e. temperature, Ga flux, group V/III flux ratio) except that in FIG. 1A the group V flux consisted of As flux only and in FIG. 1B the group V flux consisted of 50% As flux and 50% P flux. In all embodiments discussed herein the As flux is As, and the substrate was, prior to growth initiation, exposed for 5 minutes to an As flux having the same values as the As flux used in the initial (Init) step.

Ga-assisted GaAs nanowire structures are visible as narrow white lines in FIG. 1A. However, in FIG. 1B there are no nanostructures with this shape. The growth in FIG. 1B instead results in non-catalyst nucleated nanostructures, which in appearance look much like “self-catalyzed” growth without any catalyst particle, e.g. similar to what is seen for some self-catalyzed InAs nanowire growth. The difference between FIGS. 1A and 1B demonstrates that in order to form and maintain a Ga droplet, a lower group V/III ratio is needed if the group V flux comprises both an As flux and a P flux.

The image shown in FIG. 1C shows a growth which used similar growth parameters to FIGS. 1A and 1B, but where the group V/III flux ratio was lower (100 compared with 122 used in FIGS. 1A and 1B) and where the proportion of P flux in the group V flux was increased from around 5% to around 30% during the growth. The resulting growth exhibited short tapered nanowires, which are seen as squat white spikes in FIG. 1C. This shape of nanowire indicates that at some point during the growth the Ga droplet disappeared and Ga-assisted growth terminated. Based on the height of the nanowires it is estimated that the Ga droplet disappeared at either 10% or 20% P flux in the group V flux.

From the growths showed in FIGS. 1A, 1B and 1C it may be concluded that when growing Ga-assisted nanowires a lower than expected group V/III flux ratio is required when the group V flux also contains P flux, and that the maximum possible group V/III flux ratio depends on the proportion of P flux in the group V flux.

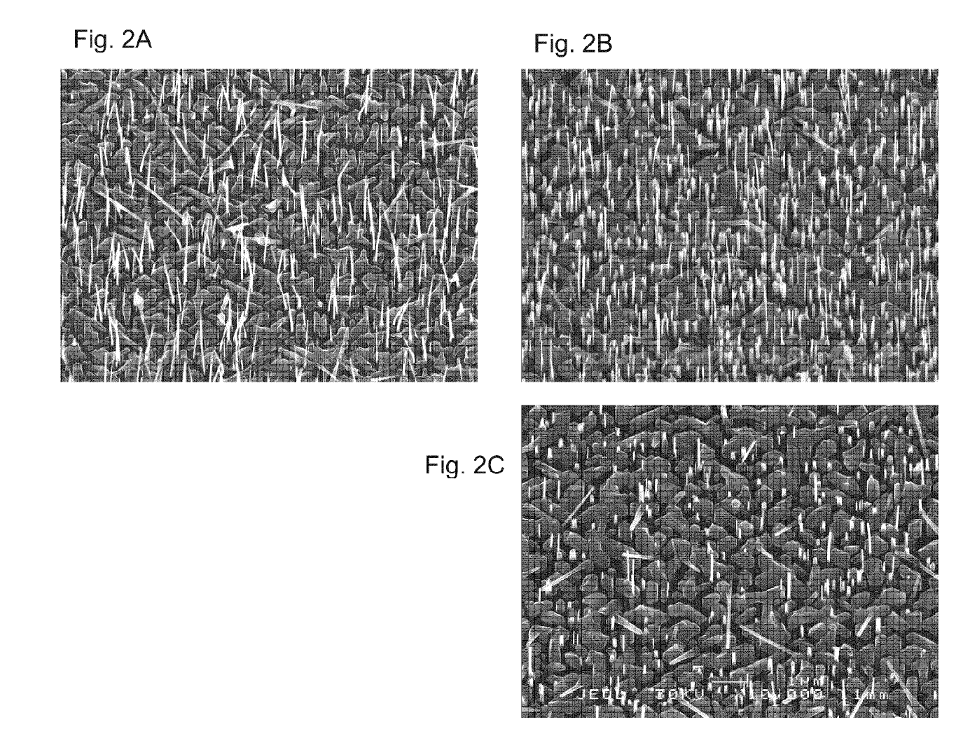

FIGS. 2A, 2B and 2C show the results of some examples of MBE-based Ga-assisted GaAsP nanostructure growth according to embodiments of the invention.

The experimental parameters used for the growths shown in FIGS. 2A, 2B and 2C are as follows:

| | | | | | Tem- |
|---|---|---|---|---|---|
| | | | | | pera- |
| | | | | Time | ture |
| FIG. 2A | Ga flux | As flux | P flux | (mins) | (° C.) |
| Init | 6.78 × 10⁻⁸ | 3.35 × 10⁻⁶ | 0.20 × 10⁻⁶ | 5 | 628 |
| Growth 1 | 6.78 × 10⁻⁸ | 2.55 × 10⁻⁶ | 0.20 × 10⁻⁶ | 8 | 628 |
| Growth 2 | 6.78 × 10⁻⁸ | 1.81 × 10⁻⁶ | 0.20 × 10⁻⁶ | 8 | 628 |
| Growth 3 | 6.78 × 10⁻⁸ | 1.34 × 10⁻⁶ | 0.33 × 10⁻⁶ | 8 | 628 |
| Growth 4 | 6.78 × 10⁻⁸ | 1.17 × 10⁻⁶ | 0.50 × 10⁻⁶ | 8 | 628 |
| Growth 5 | 6.78 × 10⁻⁸ | 1.00 × 10⁻⁶ | 0.67 × 10⁻⁶ | 8 | 628 |
| Growth 6 | 6.78 × 10⁻⁸ | 0.84 × 10⁻⁶ | 0.84 × 10⁻⁶ | 8 | 628 |

| | | | | Time | Temp | |
|---|---|---|---|---|---|---|
| FIG. 2B | Ga flux | As flux | P flux | (mins) | (° C.) | Dopant |
| Init | 6.78 × 10⁻⁸ | 3.35 × 10⁻⁶ | 0.20 × 10⁻⁶ | 2 | 633 | — |
| Growth 1 | 6.78 × 10⁻⁸ | 2.46 × 10⁻⁶ | 0.28 × 10⁻⁶ | 0.5 | 633 | — |
| Growth 2 | 6.78 × 10⁻⁸ | 2.46 × 10⁻⁶ | 0.28 × 10⁻⁶ | 69.5 | 633 | Be |
| | | | | | | 8.9 × 10⁻¹⁸ |

| | | | | Time | Temp | |
|---|---|---|---|---|---|---|
| FIG. 2C | Ga flux | As flux | P flux | (mins) | (° C.) | Dopant |
| Init | 6.78 × 10⁻⁸ | 3.35 × 10⁻⁶ | 0.20 × 10⁻⁶ | 2 | 631 | — |
| Growth 1 | 6.78 × 10⁻⁸ | 2.30 × 10⁻⁶ | 0.44 × 10⁻⁶ | 0.5 | 631 | — |
| Growth 2 | 6.78 × 10⁻⁸ | 2.30 × 10⁻⁶ | 0.44 × 10⁻⁶ | 69.5 | 631 | Be |
| | | | | | | 8.9 × 10⁻¹⁸ |

The growth conditions in these embodiments, were set to probe the effect of P in the group V material during the initial formation of Ga droplets on the substrate surface followed by the supersaturation of the droplets with group V material. During the subsequent nanowire growth the effect of using Be doping during growth was also tested.

For the growth shown in FIG. 2A, the starting conditions, i.e. the conditions for forming the Ga droplets, comprised subjecting the substrate to a Ga flux and a group V flux in a group V/III flux ratio of 52 for 5 minutes, wherein the proportion of P flux in the group V flux was about 5% (the balance being As flux).

At the end of the 5 minute initiation period, i.e. after some Ga droplets with certainty had been formed, the amount of P was increased during supersaturation and nanostructure growth from about 5% up to 50% while the group V/III flux ratio was lowered from 50 to 25. The growth temperature was 628° C. and the growth time was 53 minutes.

For the growth shown in FIG. 2B, the starting conditions comprised subjecting the substrate to a Ga flux and a group V flux in a group V/III flux ratio of 52 for 2 minutes, again wherein the proportion of P flux in the group V flux was about 5% (the balance being As flux).

In this growth, the 2 minute initiation period was followed by more than 60 minutes of growth with a group V/III flux ratio of 40 and 10% P flux in the group V flux.

The starting and growth conditions for the growth shown in FIG. 2C was the same as for FIG. 2B except that during growth the group V flux comprised 16% P flux.

The Ga flux was the same for all three growths.

Based on the results shown in FIG. 1, it may have been expected that the growths in FIGS. 2B and 2C would have resulted in a higher supersaturation of the Ga droplet by the group V materials in general and the increased group P flux in particular. Instead, however, it can be seen that the growth in FIG. 2A resulted in thin (and more densely packed) nanowires, whereas the growth in FIG. 2B resulted in thicker and somewhat shorter wires, and the growth in FIG. 2C resulted in very short and even thicker wires.

For Ga-assisted growth the diameter (i.e. transverse dimension) of the Ga-assisted nanowires is determined by the size of the Ga droplet from which it is grown. In turn the size of the droplets may depend on the level of supersaturation. Lower supersaturation may result in larger droplets being formed, and can hence influence subsequent nanowire growth. In the examples shown in FIGS. 2A, 2B and 2C, it appears that a lower supersaturation of the Ga droplet occurs as the amount of P is increased within the first 5 minutes and may hence indicate that P plays a different role during the formation of the Ga droplet than during growth of the nanowire. This change of role between droplet formation and growth initialization may then result in a poor nanowire growth. Alternatively FIGS. 2A, 2B and 2C may demonstrate the influence of using Be doping atoms during growth. The growth in FIG. 2A was done without doping while FIGS. 2B and 2C were with doping. The large difference in growth result may be completely attributed to the use of Be during the nanowire growth.

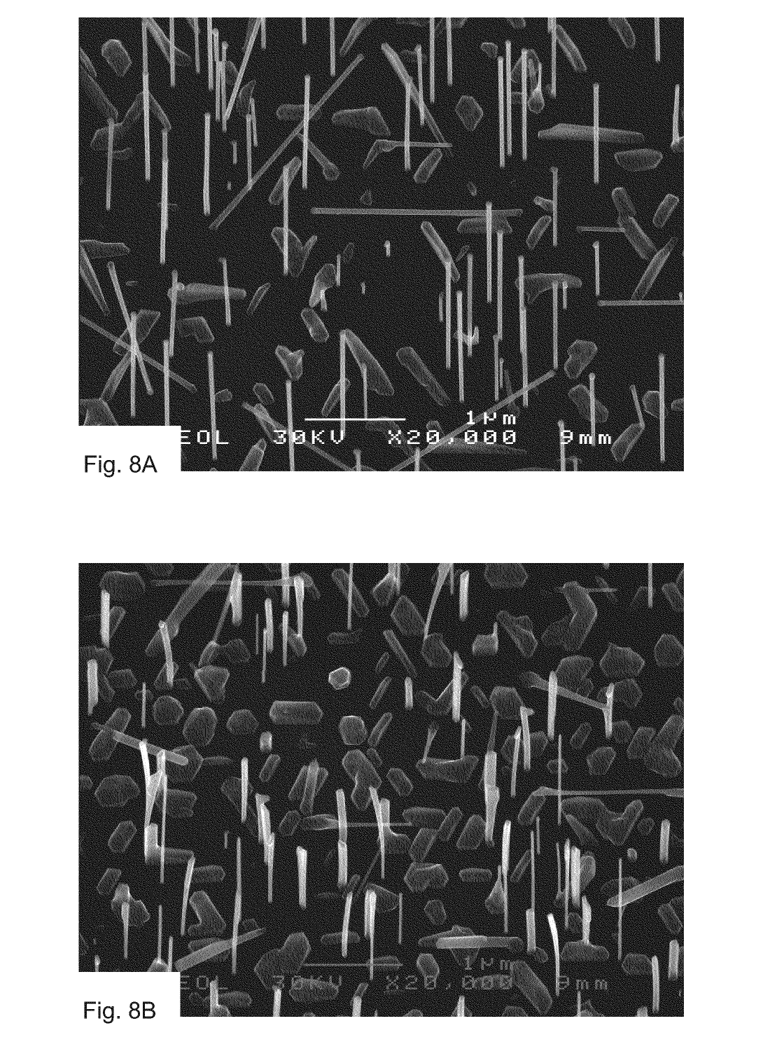

FIGS. 8A and 8B show two nanostructure growths which illustrate the influence of the use of beryllium (Be) during growth. The two growths are close to identical except that in FIG. 8B Be was used during growth. Doping with Be during growth of Ga-assisted GaAs nanowires has been tested and shown not to have a large impact on the growth morphology. Ga-assisted GaAsP nanowire growth however appear to be very sensitive to the use of even small amounts of doping during nanowire growth. This constitutes a significant difference between Ga-assisted GaAs and Ga-assisted GaAsP nanowire growth. Such a difference is unexpected and will need to be taken into account when determining the optimal growth parameters to be used when wanting to for instance make Be-doped Ga-assisted GaAsP nanowires.

The experimental parameters used for the growths shown in FIGS. 8A and 8B are as follows:

| | | | | | Tem- |
|---|---|---|---|---|---|
| | | | | | pera- |
| | | | | Time | ture |
| FIG. 8A | Ga flux | As flux | P flux | (mins) | (° C.) |
| Init | 6.78 × 10⁻⁸ | 3.86 × 10⁻⁶ | 0.20 × 10⁻⁶ | 5 | 635 |
| Growth 1 | 6.78 × 10⁻⁸ | 2.88 × 10⁻⁶ | 0.51 × 10⁻⁶ | 25 | 635 |

| | | | | Time | Temp | |
|---|---|---|---|---|---|---|
| FIG. 8B | Ga flux | As flux | P flux | (mins) | (° C.) | Dopant |
| Init | 6.78 × 10⁻⁸ | 3.95 × 10⁻⁶ | 0.20 × 10⁻⁶ | 2 | 635 | Be |
| | | | | | | 0.2 × 10⁻¹⁸ |
| Growth 1 | 6.78 × 10⁻⁸ | 3.95 × 10⁻⁶ | 0.20 × 10⁻⁶ | 3 | 635 | Be |
| | | | | | | 1.0 × 10⁻¹⁸ |
| Growth 2 | 6.78 × 10⁻⁸ | 3.00 × 10⁻⁶ | 0.53 × 10⁻⁶ | 10 | 635 | Be |
| | | | | | | 5.0 × 10⁻¹⁸ |
| Growth-3 | 6.78 × 10⁻⁸ | 3.17 × 10⁻⁶ | 0.56 × 10⁻⁶ | 25 | 635 | Be |
| | | | | | | 5.0 × 10⁻¹⁸ |

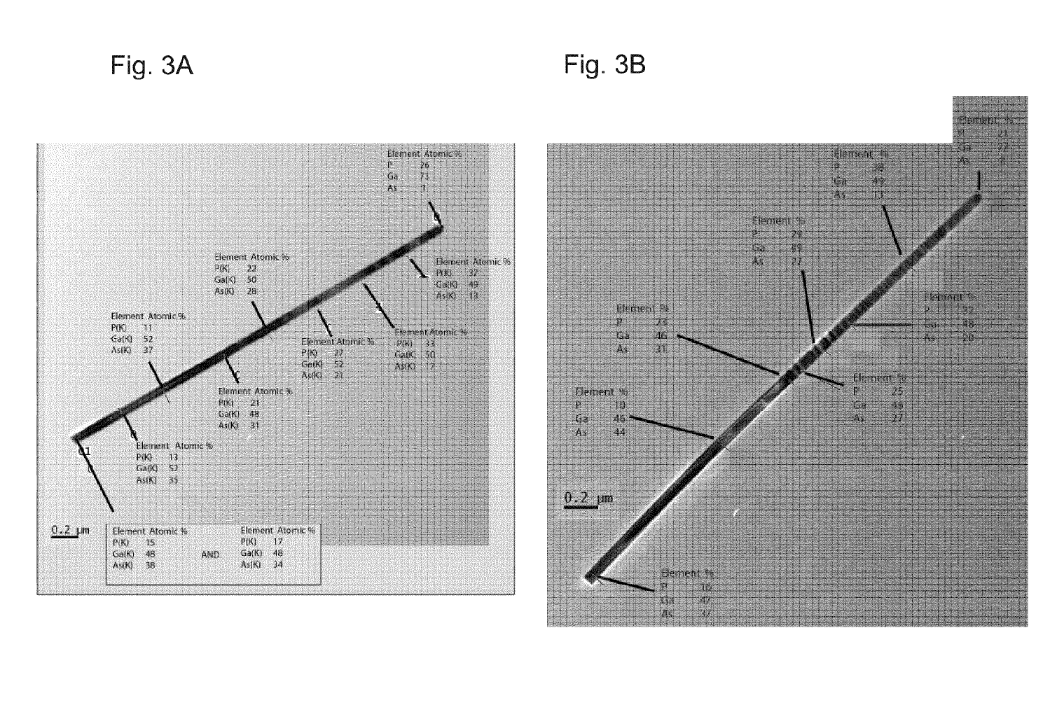

FIGS. 3 to 6 show the results of energy-dispersive X-ray (EDX) spectroscopy measurements taken on the grown nanostructures that are embodiments of the invention. These measurements reveal that the amount of P incorporated into GaAsP nanowire during Ga-assisted growth is significantly higher than for normal GaAsP bulk growth. The measurements disclosed herein characterise the content of the GaAsP nanostructures with regards to Ga, As and P with an uncertainty of about 10%, e.g. 11%±1.1%.

FIGS. 3A and 3B present nanowire data from the growth described above with reference to FIG. 2A, where the proportion of P flux in the group V flux was raised from about 5% to 50%, during growth. The data in FIGS. 3A and 3B show an approximate P content in the nanowire corresponding to between 20 and 76% of the total group V content. The percentage of P in the GaAsP nanowires shown in FIGS. 3A and 3B increases as expected during the growth. The only slight anomaly is a higher percentage of P observed at the base of the nanowire. This suggests that after the droplet has been formed and nanowire growth has begun there is a short period where an excess of P is incorporated into the nanowire.

In general for the growth shown in FIGS. 3A and 3B the proportion of P in the body of the GaAsP nanowire was 1.5 to 4 times larger than the proportion of P flux in the group V flux used for the nanostructure growth.

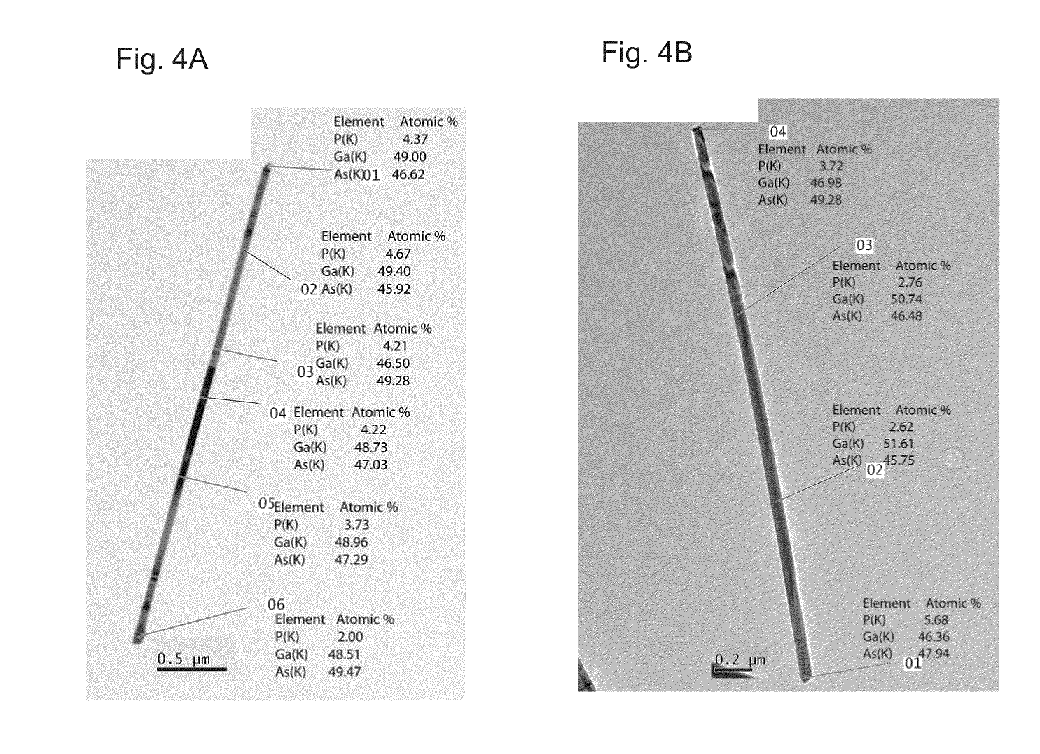

FIGS. 4A and 4B present nanowire data from the growth described above with reference to FIG. 2B, where there was a lower level of supersaturation, possibly because of the use of Be doping during growth. In this arrangement the proportion of P flux in the group V flux was 5% in the initiation of the growth and then 10% for the rest of the growth. The EDX results show that the percentage of P in the group V atoms in the nanowire is between 4 and 11%, which means that the proportion of P in the nanowire group V material was about 0.5 to 1.0 times the proportion of P flux in the group V flux during growth. Again this result may also be interpreted as the influence of using Be doping during the Ga-assisted GaAsP nanowire growth.

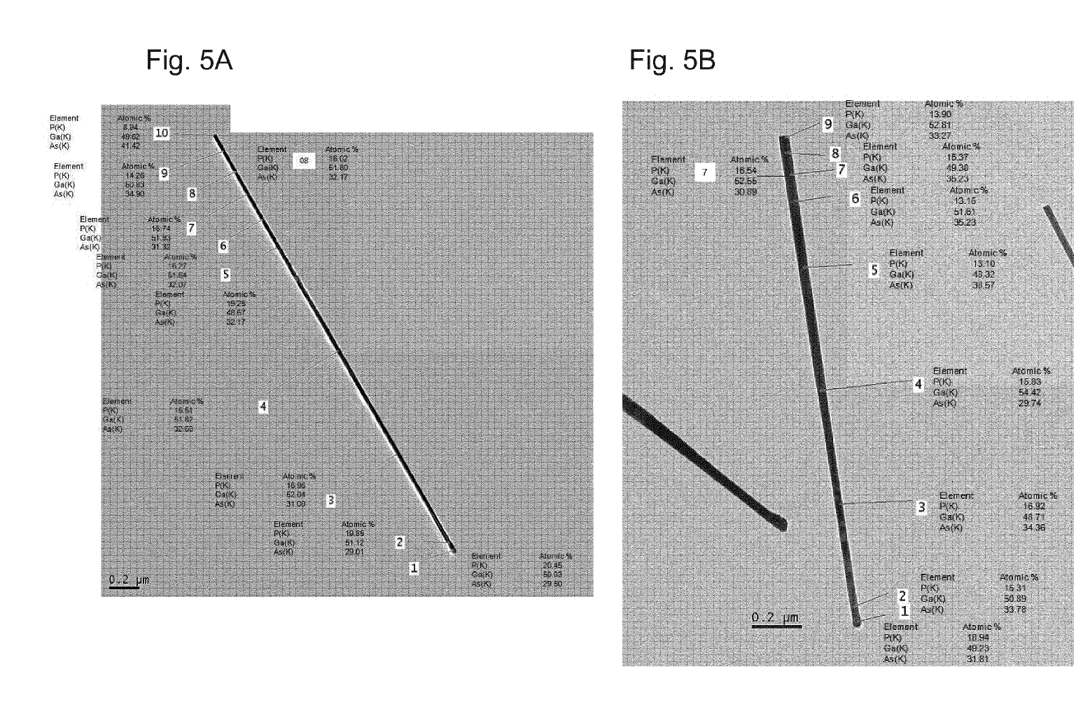

FIGS. 5A and 5B present nanowire data from a growth having the following parameters:

| | | | | | Tempera- |
|---|---|---|---|---|---|
| | | | | Time | ture |
| FIG. 5 | Ga flux | As flux | P flux | (mins) | (° C.) |
| Init | 6.78 × 10⁻⁸ | 6.58 × 10⁻⁶ | 0.20 × 10⁻⁶ | 2 | 644 |
| Growth | 6.78 × 10⁻⁸ | 4.03 × 10⁻⁶ | 0.71 × 10⁻⁶ | 28 | 644 |

In this growth, the proportion of P flux in the group V flux was about 3% in the first two minutes and then raised to 15% in the last 28 minutes. The growth was carried out at a temperature which was 10-15° C. higher than for the other growths and with a higher group V/III flux ratio than for the other growths. The EDX results in FIGS. 5A and 5B show that the amount of P in the group V material is between 28% and 40% (ignoring the abovementioned anomaly at the base of the nanowire). The proportion of P in the group V materials is therefore about 2.0 to 2.5 times the proportion of P flux in the group V flux during growth.

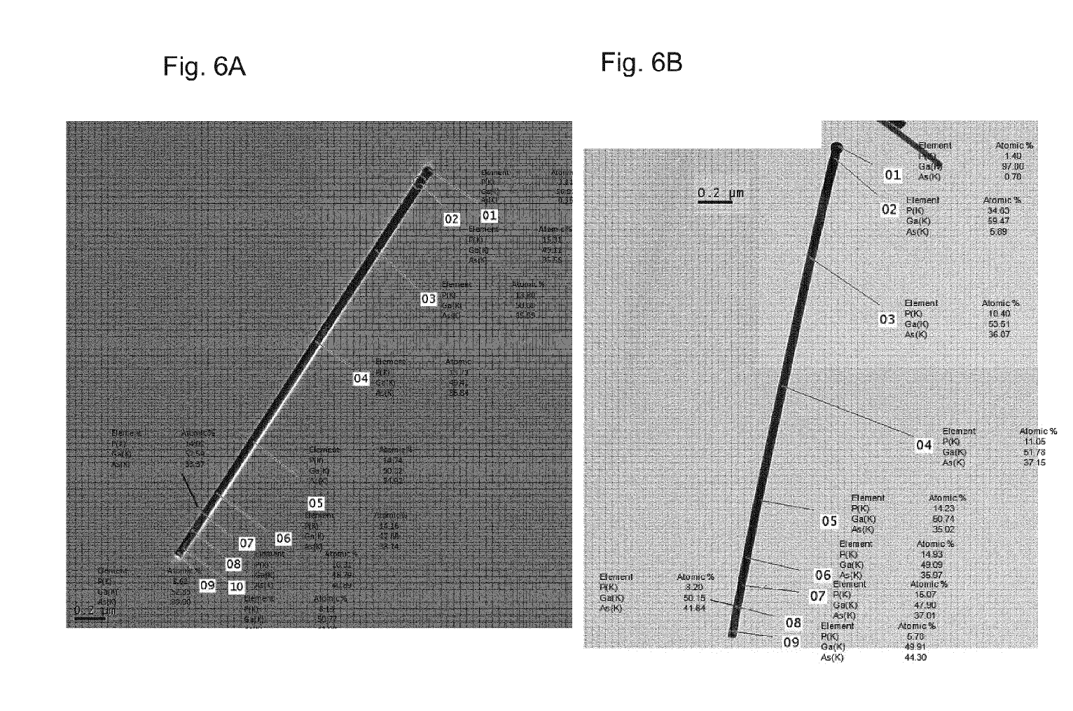

FIGS. 6A and 6B present nanowire data from a growth having the following parameters:

| | | | | | Tempera- |
|---|---|---|---|---|---|
| | | | | Time | ture |
| FIG. 6 | Ga flux | As flux | P flux | (mins) | (° C.) |
| Init | 6.78 × 10⁻⁸ | 3.86 × 10⁻⁶ | 0.20 × 10⁻⁶ | 5 | 635 |
| Growth | 6.78 × 10⁻⁸ | 2.88 × 10⁻⁶ | 0.51 × 10⁻⁶ | 25 | 635 |

This experiment has parameters similar to FIGS. 5A and 5B, except that it was done at a 10° C. lower temperature and with a lower group V/III flux ratio. The EDX results in FIGS. 6A and 6B show that the amount of P in the group V material is between 16% and 30% (again ignoring the abovementioned anomaly at the base of the nanowire). The proportion of P in the group V materials is therefore about 1.0 to 2.0 times the proportion of P flux in the group V flux during growth.

The difference in the incorporated amount of P between the growth shown in FIGS. 5 and 6 may be because of the difference in the supersaturation of the gallium droplet during growth caused by the increased group V/III flux ratio used for the growths in FIG. 5. It may also be because of the increase in growth temperature such that a higher growth temperature results in a higher amount of P being incorporated.

The general observation from the growths resulting in the nanowires shown in FIGS. 3 to 6 is that the amount of P being incorporated depends on the supersaturation of the gallium droplet during growth (i.e. the group V/III flux ratio used), the growth temperature, and perhaps also on the use of doping (which may also influence the supersaturation). The growth temperature also influences what the optimal group V/III flux ratio, to be used during the growth, is and this can therefore also influence the amount of P.

Turning to crystal quality, an inspection of the nanowire shown in FIG. 3B showed that the top part of the nanowire containing a high amount of P also contained multiple twinning defects. In contrast, the bottom part, with a lower P content, has almost no defects. An example of a growth result having a good crystal quality can be seen in FIGS. 6A and 6B, where a lower V/III ratio was used together with a lower amount of P in the group V flux. It may thus be observed that for Ga-assisted growth of GaAsP nanowires the amount of P in the group V flux influences the droplet supersaturation significantly and hence needs to be included when selecting the optimal growth parameters. In contrast, when growing Ga-assisted GaAs nanowires the droplet supersaturation is mainly determined by the growth temperature and the V/III ratio.

From Ga-assisted growth of GaAs nanowires it is known that the amount of group V and group III atoms reaching the Ga droplet on top of the wire may change during the nanowire growth. This is also expected for Ga-assisted growth of GaAsP and therefore the growth parameters may need to be modified in a similar manner during the nanowire growth to maintain a good crystal quality throughout the nanowire. Further, since the diffusion lengths and incorporation ratios of As and P is different the As/P flux ratio may also need to be adjusted during growth in order to ensure that a constant amount of P is incorporated in the GaAsP nanowire during the entire nanowire growth.

Overall, it is possible to express the proportion of P flux in the group V flux during growth as a multiple of the percentage of P that is to be incorporated in the nanowire group V atoms. That multiple may be in the range 0.2 to 2.0. Having advance knowledge of the multiple for a given growth temperature and group V/III flux ratio means that it is possible to select the amount of P to be present in the grown nanowire by adjusting the proportion of P flux in the group V flux accordingly. Surprisingly, the multiple is much lower than what would be expected for bulk GaAsP growth, which may enable greater control to be exercised over the composition of the nanowire.

The nanowire growths discussed above were carried out at temperatures greater than 629° C., i.e. in a temperature range of 630° C. to 645° C. This temperature is more than 50° C. higher than is used for Au-catalyzed growth.

The technique described above may be adapted to form core-shell p-n junctions (preferably p-i-n junctions) within the nanowire. For example, such a method may comprises a nanowire growth stage (e.g. for 50-60 mins) which may use any of the suitable conditions (e.g. growth temperature, group V/III flux ratio, etc.) and sub-stages outlined above. Following nanowire growth, the complete p-i-n structure may be created by additional bulk (i.e. thin film) GaAsP growth around the nanowire. Prior to creating the p-i-n structure the Ga droplet may be removed by transforming it to GaAsP by exposing it to a flux of As and P atoms without also supplying Ga atoms. The droplet will hence disappear and the Ga-assisted nanowire growth will stop.

The shell bulk growth may be performed at a lower temperature than the nanowire growth stage, so before the bulk growth stage there may be a cooling step (e.g. for around 10 mins) during which no growth occurs (e.g. because the Ga flux is reduced or switched off completely). For example, the nanowire growth stage may be performed at temperatures greater than 600° C., e.g. 635° C., whereas the bulk growth may be performed at temperatures less than 550° C. In addition, as mentioned above, bulk growth of GaAsP requires a higher proportion of P in the group V flux to achieve the equivalent proportion of P atoms in the group V atoms of the deposited structure. Accordingly, the P proportion in the group V flux during bulk growth is increased (e.g. to greater than 30% or greater than 35) in order to provide a proportion of P atoms in the deposited bulk layer that matches the proportion of P atoms in the nanowire.

Following the cooling step, a first bulk growth stage may be performed in which a p-type dopant (e.g. Be) is included in the flux. A p-doped layer may thus be formed on the nanowire.

Following the first bulk growth stage, there may be a heating step to promote diffusion of the dopant into the nanowire, e.g. to increase the uniformity of the p-type conductivity throughout the structure and form a p-type core. During the heating step no growth occurs (e.g. because the Ga flux is reduced or switched off completely). The temperature of the heating step may be greater than that possible for bulk growth, i.e. greater than 550° C. (e.g. 600° C.). The heating may take place for 10 minutes or more, e.g. 20 minutes.

The heating step may end with a cooling period in which the temperature is returned to a level suitable for bulk growth.

Following the heating step and cooling period, a second bulk growth stage may be performed, in which an intrinsic (i-type) layer is grown over the p-type core. No doping is present during this growth stage.

Following the second bulk growth stage, a third bulk growth stage may be performed in which an n-type dopant (e.g. Si) is introduced into the flux such that an n-type layer is formed on the i-type layer.

Following the third bulk growth stage, the process may terminate with a cooling period or by further growth of a surface passivation and/or contact layer.

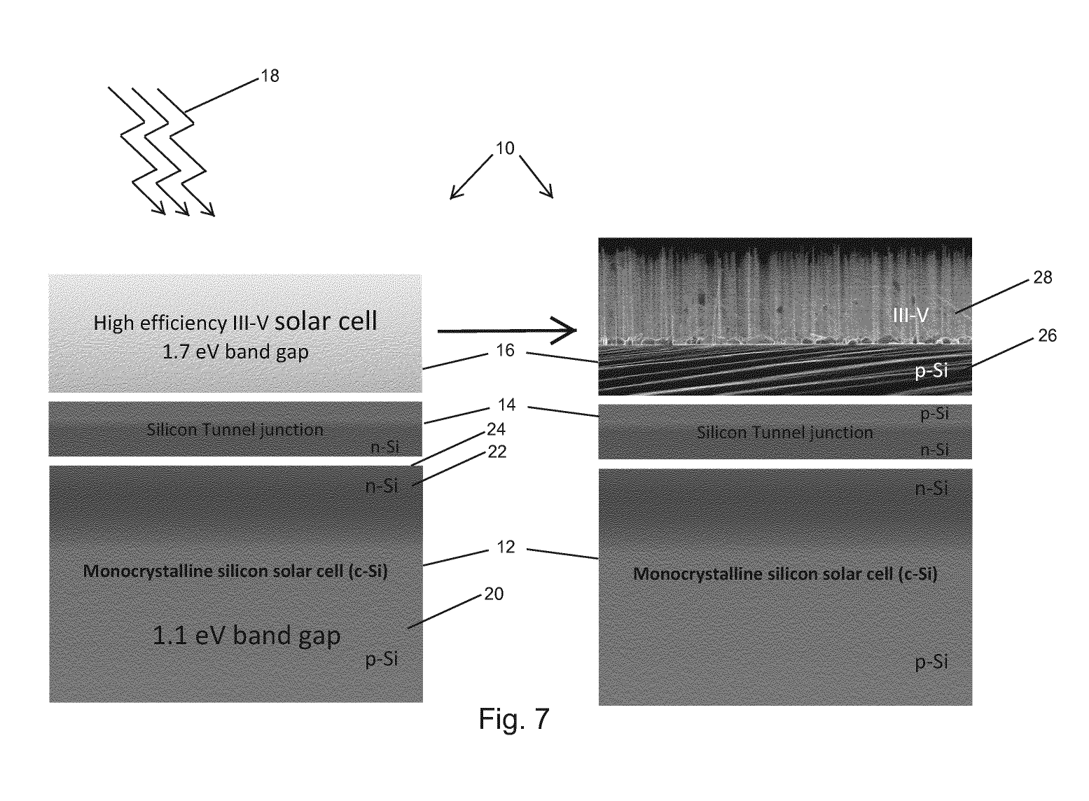

FIG. 7 is a schematic cross-sectional view of a multi-junction photovoltaic cell 10 that is an embodiment of the invention. The photovoltaic cell has a substrate 12 formed of monocrystalline silicon. The silicon substrate 12 comprises a first region 20 having a first conductivity type (in this example p-type, indicating that holes are the primary charge carrier) and a second region 22 having a second conductivity type (in this example n-type, indicating that electrons are the primary charge carrier) formed thereon. The second region 22 can be formed by diffusing a dopant (electron donor) into the silicon from its upper surface 24 (i.e. the surface facing towards incident light 18), before forming the tunnel junction 14 and nanowire region 16 discussed below. The first and second regions together form a first p-n junction for the photovoltaic cell. A region of intrinsic silicon (not shown) may be formed between the first region 20 and second region 22 to form a p-i-n type junction. The band gap of the silicon in the junction may be about 1.1 eV.

A conventional tunnel junction 14 (in this case made of silicon) is formed (i.e. grown) on the upper surface 24 of the substrate 12. The tunnel junction may be excluded or be a heterojunction between the silicon and the nanowires.

On the other side of the tunnel junction 14 from the first p-n junction is a nanowire region 16 that forms a second p-n junction. The nanowire region 16 comprises a base layer (substrate) 26 of silicon (in this example p-type silicon) on which a plurality of GaAsP nanowires 28 are grown using the Ga-assisted MBE technique discussed above. The GaAsP nanowires 28 have a p-type core region and are subsequently coated in an n-type shell region to form a second p-n junction for the photovoltaic cell. A region of intrinsic GaAsP (not shown) may be formed between the p-type region and n-type region to form a p-i-n type junction. The band gap of the GaAsP in the second p-n junction may be about 1.7 eV.

To complete the cell, electrical contacts (not shown) may be provided on the bottom surface of the substrate 12 and the top surface of the nanowire region 16. The electrical contact at the top surface may comprise a transparent conductor to enable incident light 18 to reach the p-n junctions in the cell.

The silicon substrate 26 may be prepared for GaAsP nanowire fabrication using a nanoimprint lithographic process having the following steps. Firstly a layer of oxide (e.g. having a thickness of 40 nm) is grown on the silicon substrate 26, e.g. by means of a dry thermal oxidation technique. Secondly, a planarization layer and a subsequent imprint layer are deposited on top of the layer of oxide. Thirdly, an array or pattern of oxide free holes are formed by using a suitable imprint stamp to compact the imprint layer at each hole location, i.e. such that the imprint layer is substantially thinner where each oxide free hole is to be located. Fourthly, two reactive ion etch (RIE) steps are performed. The first RIE step removes a small amount of the imprint layer to thereby expose the planarization layer underneath. The second RIE step removes the planarization layer in the areas where this is exposed through the imprint layer. The effect of these steps is to expose the oxide layer at each hole location. Fifthly, the exposed oxide layer is etched with RIE and hydrofluoric acid. It is preferable for most of the oxide layer to be removed by the RIE etch since this gives the best etch profile but for the final few nanometres of oxide to be removed using hydrofluoric acid since this leaves a more clean silicon surface at the bottom of the etched holes. Sixthly, the remaining planarization layer and imprint layer are be removed and the substrate cleaned using a RCA cleaning process. Finally, before beginning the nanostructure fabrication, an additional HF etching step can be carried out to remove any native oxide that may have re-grown in the etched holes.

The silicon substrate 26 may also be provided with a patterned array of oxide free holes by using deep UV-lithography and subsequent etching steps. The array can also be fabricated by depositing on the silicon substrate a layer of spin-on-glass (or similar) into which the imprint pattern then can be imprinted and the spin-on-glass afterwards cured such that it forms a layer with the same properties as silicon oxide. A short etch step will then ensure that the patterned holes are completely oxide free whereas silicon oxide like spin-on-glass still covers the rest of the silicon substrate.

The GaAsP nanowires 28 grown on the substrate 26 may have surface passivation applied thereto, e.g. by growing an additional shell of highly n-doped InGaP using conventional epitaxial methods. Applying surface passivation in this way may increase the peak conversion efficiency of the nanowire. Peak efficiencies greater than 10% are possible.

### REFERENCES

[1] Epitaxial III-V Nanowires on Silicon, NANO LETT. Vol. 4, No. 10, 1987-1990 (2004)—Thomas Mårtensson, C. Patrik T. Svensson, Brent A. Wacaser, Magnus W. Larsson, Werner Seifert, Knut Deppert, Anders Gustafsson, L. Reine Wallenberg and Lars Samuelson
[2] Chemical potentials for Au-assisted vapor-liquid-solid growth of III-V nanowires, J. Appl. Phys. 108, 073506 (2010)—Frank Glas
[3] Nucleation mechanism of gallium-assisted molecular beam epitaxy growth of gallium arsenide nanowires, APPLIED PHYSICS LETTERS 92, 063112 (2008)—A. Fontcuberta i Morral, C. Colombo, G. Abstreiter, J. Arbiol and J. R. Morante
[4] Ga-assisted catalyst-free growth mechanism of GaAs nanowires by molecular beam epitaxy, PHYSICAL REVIEW B 77, 155326 (2008)—C. Colombo, D. Spirkoska, M. Primmer, G. Abstreiter, and A. Fontcuberta i Morral
[5] Gold-free growth of GaAs nanowires on silicon: arrays and polytypism, Nanotechnology 21, 385602 (2010)—Sébastien Plissard, Kimberly A Dick, Guilhem Larrieu, Sylvie Godey, Ahmed Addad, Xavier Wallart and Philippe Caroff
[6] Kinetic Control of Self-Catalyzed Indium Phosphide Nanowires, Nanocones, and Nanopillars, Nano Lett., Vol. 9, No. 6, June 2009, p. 2207-2211—Robyn L. Woo, Li Gao, Niti Goel, Mantu K. Hudait, Kang L. Wang, Suneel Kodambaka and Robert F. Hicks
[7] Catalyst-free growth of In(As)P nanowires on silicon, Appl. Phys. Lett. 89, 063119 (2006)—M. Mattila, T. Hakkarainen, H. Lipsanen, H. Jiang and E. I. Kauppinen
[8] Composition control of GaAsP grown by molecular beam epitaxy, Journal of Crystal growth 111 (1991) p. 61-64.—Takashi Nomura, Hiroshi Ogasawara, Masahiro Miyao and Minoru Hagino.
[9] Suitability of Au- and Self-Assisted GaAs Nanowires for Optoelectronic Applications, Nano Lett. 2011, 11, 1276-1279—Steffen Breuer, Carsten Pfüller, Timur Flissikowski, Oliver Brandt, Holger T. Grahn, Lutz Geelhaar and Henning Riechert.
[10] Direct Imaging of Single Au Atoms with GaAs Nanowires, Nano Lett. 2012, 12, 2352-2356—Maya Bar-Sadan, Juri Barthel, Hadas Shtrikman, and Lothar Houben.
[11] Influence of substitutional metallic impurities on the performances of p-type crystalline silicon solar cells: The case of gold. Journal of Applied Physics 100, 123502 (2006)—S. Dubois, O. Palais, M. Pasquinelli, S. Martinuzzi and C. Jaussaud.

1. An Au-free GaAsP nanostructure resulting from Ga-assisted growth.

2. A nanostructure according to claim 1, wherein the proportion of As in the group V material is 65% to 90% and the proportion of P in the group V material is 10% to 35%.

3. A nanostructure according to claim 1, wherein the GaAsP has a band gap in the range 1.6 to 1.8 eV.

4. A nanostructure according to claim 1 comprising a nanowire extending in a longitudinal direction, wherein the nanowire has a maximum transverse dimension less than 150 nm.

5. A semiconductor device comprising:
a silicon substrate; and
a plurality of GaAsP nanostructures according to claim 1 grown on the silicon substrate by Ga-assisted growth.

6. A semiconductor device according to claim 5, wherein the plurality of GaAsP nanostructures comprise a plurality of nanowires, each nanowire extending in a longitudinal direction from a surface of the substrate, the longitudinal direction being normal to the surface of the substrate.

7. A photovoltaic cell comprising an active element having the semiconductor device of claim 5, in which the silicon in the substrate forms a first p-n junction and the GaAsP in the nanostructures forms a second p-n junction.

8. A photovoltaic cell according to claim 7, wherein:
the silicon substrate comprises:
a first silicon layer having a first conductivity type;
a second silicon layer having a second conductivity type, the first and second silicon layers being disposed to form the first p-n junction; and
each GaAsP nanostructure having:
a core region surrounded by a shell region, the core region being formed from one of the first and second conductivity types and the shell region being formed from the other of the first and second conductivity types to form a second n-p junction.

9. A photovoltaic cell according to claim 7 comprising a third p-n junction between the first and second p-n junctions.

10. A photovoltaic cell according to claim 9, wherein the third p-n junction is formed in the silicon substrate or in each GaAsP nanostructure or at an interface therebetween.

11. A vapour-liquid-solid (VLS) method of growing a GaAsP nanostructure, the method comprising:
subjecting a silicon oxide surface layer on a substrate to a Ga flux to form Ga droplets on the surface layer;
subjecting the Ga droplets to the Ga flux and a group V flux to supersaturate the Ga droplets with group V atoms from the group V flux, the group V flux comprising an As flux and, optionally, a P flux;
setting a growth temperature, a non-zero proportion of P flux in the group V flux, and the Ga flux and the group V flux in a V/III flux ratio to effect growth of a GaAsP nanostructure at each supersaturated Ga droplet.

12. A method according to claim 11, wherein the substrate is silicon and the method further comprises:
before subjecting the silicon oxide surface to a Ga flux, etching a plurality of holes in the silicon oxide surface layer to create an array of oxide free holes for receiving the Ga droplets in direct contact with the silicon.

13. A method according to claim 11, wherein the proportion of P flux in the group V flux is initiated at a predetermined multiple of the proportion of P relative to the total amount of group V atoms to be present in the grown GaAsP nanostructure.

14. A method according to claim 13, wherein the predetermined multiple is in the range 0.1 to 6.

15. A method according to claim 11 including changing the proportion of P flux in the group V flux after forming the plurality of Ga droplets.

16. A method according to claim 11, wherein the set growth temperature is greater than 570° C., and preferably higher than 600° C.

17. A method according to claim 11, wherein during the growth temperature is in the range 620° C. to 650° C. and the V/III flux ratio is less than 120.

18. A method according to claim 13 including selecting the predetermined multiple based on the growth temperature, the VIII flux ratio and the ratio of the number of P atoms in P molecules in the P flux to the number of As atoms in As molecules in the As flux.

19. A method according to claim 11 including forming a silicon oxide layer on the substrate before subjecting it to the Ga flux.

20. A method according to claim 11 including doping the nanostructure.

21. A method according to claim 20, wherein doping comprises introducing a dopant flux during growth.

22. A method according to claim 20, wherein doping comprises overgrowing each nanostructure with a doped GaAsP shell after the nanostructure is grown.
